(19) United States
(12) Patent Application Publication
(10) Pub. No.: US 2025/0264815 A1
(43) Pub. Date: Aug. 21, 2025

(54) THERMALLY ACTUATED COOLING SYSTEM

(71) Applicant: ASML Netherlands B.V., Veldhoven (NL)

(72) Inventors: Wyatt DUVALL, San Diego, CA (US); Ethan Marcus SWERDLOW, San Diego, CA (US)

(73) Assignee: ASML Netherlands B.V., Veldhoven (NL)

(21) Appl. No.: 18/859,485

(22) PCT Filed: Mar. 20, 2023
(86) PCT No.: PCT/EP2023/057026

§ 371 Date: Oct. 23, 2024

Related U.S. Application Data
(60) Provisional application No. 63/335,118, filed on Apr. 26, 2022.

(51) Int. Cl. G03F 7/00

(52) U.S. Cl. CPC G03F 7/70891; G03F 7/70033; G03F 7/702; G03F 7/70316

(57) ABSTRACT

Systems, apparatuses, and methods are provided for manufacturing a thermally actuated cooling apparatus. An example method can include providing a cooling member. The cooling member can include a contact plate, fins extending from the contact plate in a first direction, and a protuberance extending from the contact plate in a second direction. Subsequently, the example method can include mounting the protuberance to a part of an extreme ultraviolet (EUV) radiation source. The contact plate can include a first coefficient of thermal expansion (CTE) that is greater than a second CTE of the part.

### CROSS REFERENCE TO RELATED APPLICATIONS

This application claims priority to U.S. Application No. 63/335,118, filed Apr. 26, 2022, titled THERMALLY ACTUATED COOLING SYSTEM, which is incorporated herein in its entirety by reference.

### TECHNICAL FIELD

The present disclosure relates to thermally actuated cooling systems, apparatuses, and methods of manufacture.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which may be a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Extreme ultraviolet (EUV) radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

### SUMMARY

The present disclosure describes various aspects of systems, apparatuses, and methods for manufacturing and using a thermally actuated cooling system in an extreme ultraviolet (EUV) radiation source.

In some aspects, the present disclosure describes a system. The system can include a cooling member. The cooling member can include a contact plate, fins extending from the contact plate in a first direction, and a protuberance extending from the contact plate in a second direction and configured to couple the contact plate to a part of an EUV radiation source. The part can include a heating element. The contact plate can include a first coefficient of thermal expansion (CTE) that is greater than a second CTE of the part.

In some aspects, the present disclosure describes an apparatus. The apparatus can include a contact plate and a protuberance extending from the contact plate and configured to couple the contact plate to a part of an EUV radiation source. The protuberance is configured to be in a physically strained relationship with the part such that when the part is heated, a first surface of the contact plate is configured to disengage from a second surface of the part, and when the part is not exposed to heat, the first surface of the contact plate is configured to contact the second surface of the part.

In some aspects, the present disclosure describes a method for manufacturing an apparatus. The method can include providing a cooling member. The cooling member can include a contact plate, fins extending from the contact plate in a first direction, and a protuberance extending from the contact plate in a second direction. The method can further include mounting the protuberance to a part of an EUV radiation source. The contact plate can include a first CTE that is greater than a second CTE of the part. In some aspects, when the part is exposed to heat, a first surface of the contact plane is configured to disengage from a second surface of the part.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of an example radiation source for an example reflective lithographic apparatus according to some aspects of the present disclosure.

FIGS. 5A and 5B are schematic illustrations of an example thermally actuated cooling system according to some aspects of the present disclosure.

FIG. 6 is a graphical representation of an example notional cooling profile resulting from an addition of an example thermally actuated cooling system to a part of a lithographic apparatus, according to some aspects of the present disclosure.

FIG. 7 is an example method for manufacturing an apparatus according to some aspects of the present disclosure or portion(s) thereof.

FIG. 8 is an example computer system for implementing some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an exemplary embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., +10%, +20%, or +30% of the value).

### Overview

In some aspects, EUV radiation source components, such as the droplet generator assembly (DGA), must be cooled down before they can be serviced. In one example, heat sinks can be used to dissipate heat from an EUV radiation source by using two thermally mismatched materials contacting each other, such as a heat sink made of a material having excellent heat dissipation and interdigitized engagement with the heat generating component. In another example, natural convection, forced convection, fins, or Peltier elements (e.g., thermoelectric devices) can be utilized to cool the EUV radiation source.

However, these techniques often require additional power or flow input. For example, the addition of cooling water to cool the DGA would result in excessive vibrations, which would adversely affect droplet stability. In another example, adding fins to the DGA to enhance convection would require additional power during operation to maintain operational temperatures, which would put additional strain on the electrical infrastructure and unnecessarily waste energy.

Additionally, cooling times using these techniques are too long and extend system downtimes. For instance, several components on the EUV radiation source operate above touch-safe temperatures and must be cooled before service actions. This cooling time often takes over an hour, which adds to mean time to repair (MTTR) and additional machine downtime.

In contrast, some aspects of the present disclosure can provide for a thermally actuated cooling system that includes a heat sink with fins and a threaded post with a stainless steel insert that is torque-fit into a heat generating EUV component, such as a DGA, creating strain. When heated, the heat sink expands and, when the strain of the thread is relieved, the heat sink lifts off of the heat generating EUV component.

In some aspects, the present disclosure provides for a thermally actuated cooling system that includes a cooling member coupled to a molybdenum member by a threaded protuberance partially surrounded by an insert and received in a receptacle in the molybdenum member, the cooling member includes a contact plate and rods extending therefrom and having a higher CTE than molybdenum. The threaded protuberance is in a physically strained relationship with the molybdenum member such that heating causes a contact plate surface to disengage from a molybdenum member surface and cooling causes the contact plate surface to contact the molybdenum member surface to cool the molybdenum member.

There are many exemplary aspects to the thermally actuated cooling systems, apparatuses, and methods disclosed herein. For example, aspects of the present disclosure provide for faster cooling times for cooling components associated with the EUV radiation source in preparation for service actions. In yet another example, the present disclosure provides for reductions in MTTR and mean time between intervals (MTBI).

Before describing such aspects in more detail, however, it is instructive to present an example environment in which aspects of the present disclosure can be implemented.

### Example Lithographic Systems

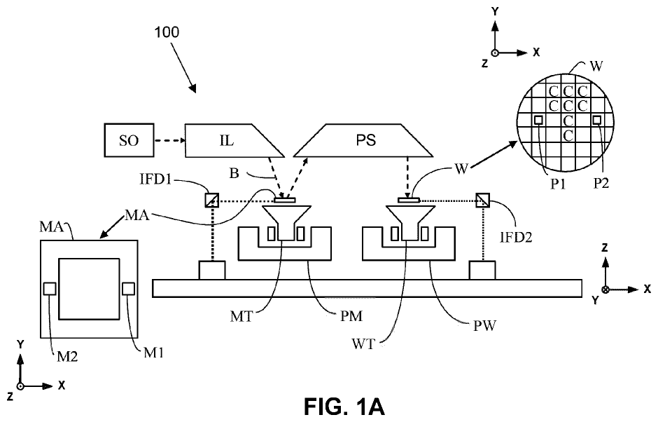

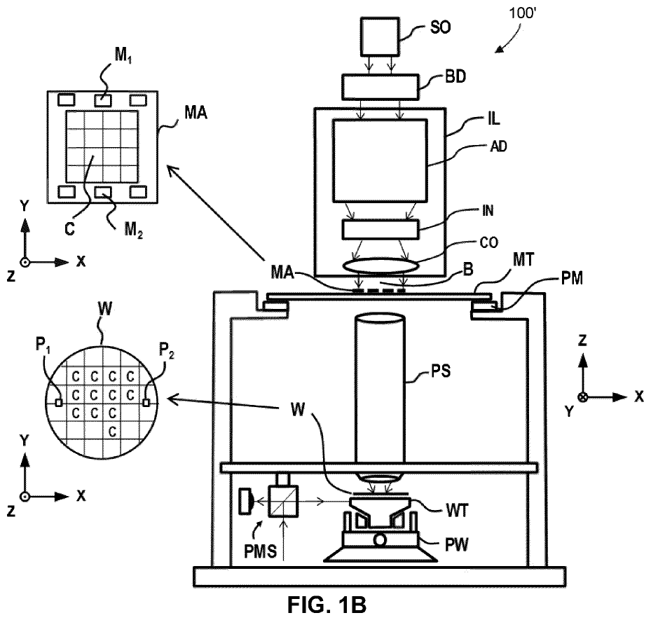

FIGS. 1A and 1B are schematic illustrations of a lithographic apparatus 100 and a lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a deep ultra violet (DUV) radiation beam or an extreme ultra violet (EUV) radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100′ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IF2 (e.g., an interferometric device, linear encoder, or capacitive sensor), the substrate table WT can be moved accurately, e.g., so as to position different target portions C in the path of the radiation beam B. Similarly, the first positioner PM and another position sensor IF1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are known as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system IPU pupil. In some aspects, portions of radiation can emanate from the intensity distribution at the illumination system pupil IPU and traverse a mask pattern without being affected by diffraction at the mask pattern MP and create an image of the intensity distribution at the illumination system pupil IPU.

The projection system PS projects an image of the mask pattern MP, where the image is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Reflected light (e.g., zeroth-order diffracted beams) traverses the pattern without any change in propagation direction. The zeroth-order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth-order diffracted beams is an image of the intensity distribution in the illumination system pupil IPU of the illumination system IL. In some aspects, an aperture device PD can be disposed at, or substantially at, a plane that includes the pupil conjugate PPU of the projection system PS.

The projection system PS is arranged to capture, by means of a lens or lens group, not only the zeroth-order diffracted beams, but also first-order or first- and higher-order diffracted beams (not shown). Some aspects are described in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position sensor IFD (e.g., an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot IVR can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot IVR. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:
1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.
2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-)magnification and image reversal characteristics of the projection system PS.
3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV radiation source configured to generate an EUV radiation beam B for EUV lithography. In general, the EUV radiation source can be configured in a radiation source SO, and a corresponding illumination system IL can be configured to condition the EUV radiation beam B of the EUV radiation source.

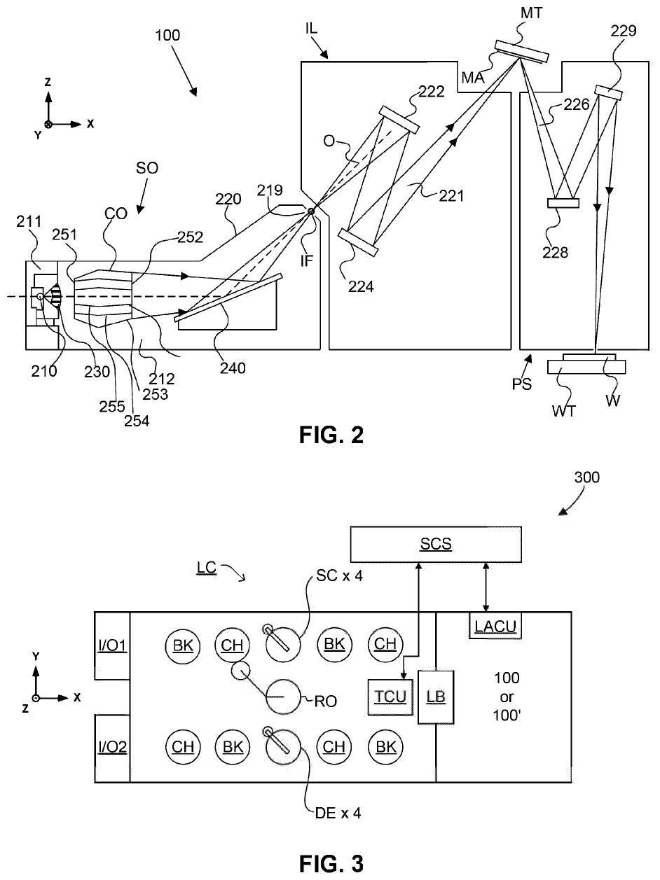

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in the source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point INTF. The virtual source point INTF is commonly referred to as the intermediate focus, and the source collector apparatus is arranged such that the virtual source point INTF is located at or near an opening 219 in the enclosing structure 220. The virtual source point INTF is an image of the EUV radiation emitting plasma 210. The grating spectral filter 240 can be used to suppress infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

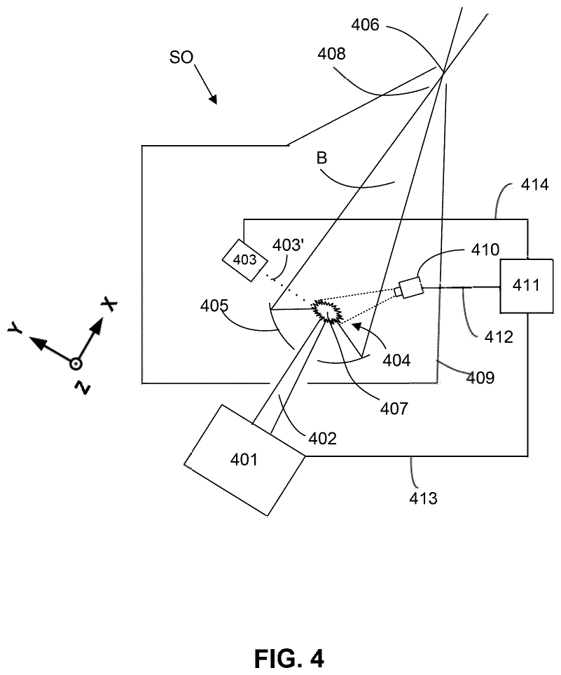

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Radiation Source

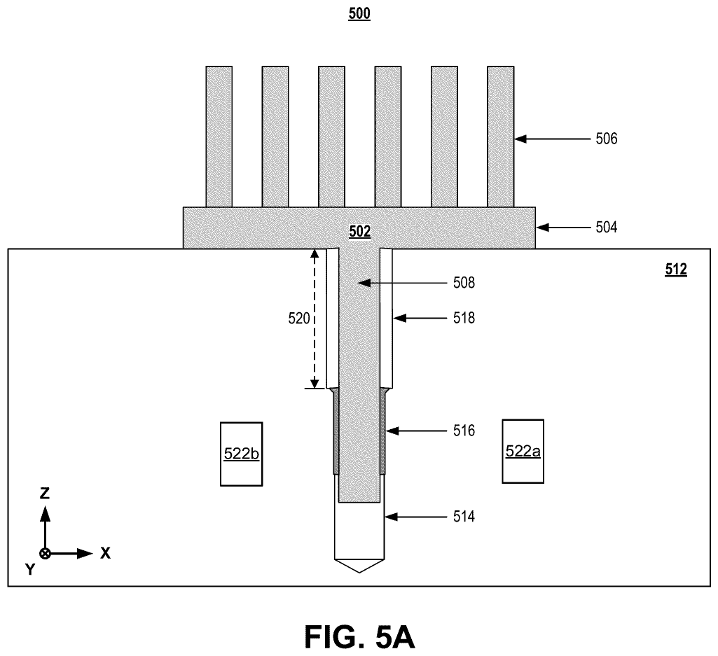

An example of the radiation source SO for a reflective lithographic apparatus (e.g., lithographic apparatus 100 of FIG. 1A) is shown in FIG. 4. As shown in FIG. 4, the radiation source SO is illustrated from a point of view (e.g., a top view) that is normal to the XY plane as described below.

The radiation source SO shown in FIG. 4 is of a type which can be referred to as a laser produced plasma (LPP) source. A laser system 401, which can include, for example, a carbon dioxide (CO₂) laser, is arranged to deposit energy via one or more laser beams 402 into fuel targets 403′, such as one or more discrete tin (Sn) droplets, which are provided from a fuel target generator 403 (e.g., a fuel emitter, a droplet generator assembly (DGA)). According to some aspects, laser system 401 can be, or can operate in the fashion of, a pulsed, continuous wave or quasi-continuous wave laser. The trajectory of fuel targets 403′ (e.g., droplets) emitted from the fuel target generator 403 can be parallel to an X-axis. According to some aspects, the one or more laser beams 402 propagate in a direction parallel to a Y-axis, which is perpendicular to the X-axis. A Z-axis is perpendicular to both the X-axis and the Y-axis and extends generally into (or out of) the plane of the page, but in other aspects, other configurations are used. In some embodiments, the laser beams 402 can propagate in a direction other than parallel to the Y-axis (e.g., in a direction other than orthogonal to the X-axis direction of the trajectory of the fuel targets 403′).

In some aspects, the one or more laser beams 402 can include a pre-pulse laser beam and a main pulse laser beam. In such aspects, the laser system 401 can be configured to hit each of the fuel targets 403′ with a pre-pulse laser beam to generate a modified fuel target. The laser system 401 can be further configured to hit each of the modified fuel targets with a main pulse laser beam to generate the plasma 407.

Although tin is referred to in the following description, any suitable target material can be used. The target material can be, for example, in liquid form, and can be, for example, a metal or alloy. Fuel target generator 403 can include a nozzle configured to direct tin, e.g., in the form of fuel targets 403′ (e.g., discrete droplets) along a trajectory towards a plasma formation region 404. Throughout the remainder of the description, references to “fuel”, “fuel target” or “fuel droplet” are to be understood as referring to the target material (e.g., droplets) emitted by fuel target generator 403. Fuel target generator 403 can include a fuel emitter. The one or more laser beams 402 are incident upon the target material (e.g., tin) at the plasma formation region 404. The deposition of laser energy into the target material creates a plasma 407 at the plasma formation region 404. Radiation, including EUV radiation, is emitted from the plasma 407 during de-excitation and recombination of ions and electrons of the plasma.

The EUV radiation is collected and focused by a radiation collector 405 (e.g., radiation collector CO). In some aspects, radiation collector 405 can include a near normal-incidence radiation collector (sometimes referred to more generally as a normal-incidence radiation collector). The radiation collector 405 can be a multilayer structure, which is arranged to reflect EUV radiation (e.g., EUV radiation having a desired wavelength such as about 13.5 nm). According to some aspects, radiation collector 405 can have an ellipsoidal configuration, having two focal points. A first focal point can be at the plasma formation region 404, and a second focal point can be at an intermediate focus 406, as discussed herein.

In some aspects, laser system 401 can be located at a relatively long distance from the radiation source SO. Where this is the case, the one or more laser beams 402 can be passed from laser system 401 to the radiation source SO with the aid of a beam delivery system (not shown) including, for example, suitable directing mirrors and/or a beam expander, and/or other optics. Laser system 401 and the radiation source SO can together be considered to be a radiation system.

Radiation that is reflected by radiation collector 405 forms a radiation beam B. The radiation beam B is focused at a point (e.g., the intermediate focus 406) to form an image of plasma formation region 404, which acts as a virtual radiation source for the illumination system IL. The point at which the radiation beam B is focused can be referred to as the intermediate focus (IF) (e.g., intermediate focus 406). The radiation source SO is arranged such that the intermediate focus 406 is located at or near to an opening 408 in an enclosing structure 409 of the radiation source SO.

The radiation beam B passes from the radiation source SO into the illumination system IL, which is configured to condition the radiation beam B. The radiation beam B passes from the illumination system IL and is incident upon the patterning device MA held by the support structure MT. The patterning device MA reflects and patterns the radiation beam B. Following reflection from the patterning device MA the patterned radiation beam B enters the projection system PS. The projection system includes a plurality of mirrors, which are configured to project the radiation beam B onto a substrate W held by the substrate table WT. The projection system PS can apply a reduction factor to the radiation beam, forming an image with features that are smaller than corresponding features on the patterning device MA. For example, a reduction factor of four can be applied. Although the projection system PS is shown as having two mirrors in FIG. 2, the projection system can include any number of mirrors (e.g., six mirrors).

The radiation source SO can also include components which are not illustrated in FIG. 4. For example, a spectral filter can be provided in the radiation source SO. The spectral filter can be substantially transmissive for EUV radiation but substantially blocking for other wavelengths of radiation such as infrared radiation.

The radiation source SO (or radiation system) can further include a fuel target imaging system to obtain images of fuel targets (e.g., droplets) in the plasma formation region 404 or, more particularly, to obtain images of shadows of the fuel targets. The fuel target imaging system can detect light diffracted from the edges of the fuel targets. References to images of the fuel targets in the following text should be understood also to refer to images of shadows of the fuel targets or diffraction patterns caused by the fuel targets.

The fuel target imaging system can include a photodetector such as a CCD array or a CMOS sensor, but it will be appreciated that any imaging device suitable for obtaining images of the fuel targets can be used. It will be appreciated that the fuel target imaging system can include optical components, such as one or more lenses, in addition to a photodetector. For example, the fuel target imaging system can include a camera 410, e.g., a combination of a photosensor or photodetector and one or more lenses. The optical components can be selected so that the photosensor or camera 410 obtains near-field images and/or far-field images. The camera 410 can be positioned within the radiation source SO at any appropriate location from which the camera has a line of sight to the plasma formation region 404 and one or more markers (not shown in FIG. 4) provided on the radiation collector 405. In some aspects, however, it can be desirable to position the camera 410 away from the propagation path of the one or more laser beams 402 and from the trajectory of the fuel targets emitted from fuel target generator 403 so as to avoid damage to the camera 410. According to some aspects, the camera 410 is configured to provide images of the fuel targets to a controller 411 via a connection 412. The connection 412 is shown as a wired connection, though it will be appreciated that the connection 412 (and other connections referred to herein) can be implemented as either a wired connection or a wireless connection or a combination thereof.

As shown in FIG. 4, the radiation source SO can include a fuel target generator 403 configured to generate and emit fuel targets 403′ (e.g., discrete tin droplets) towards a plasma formation region 404. The radiation source SO can further include a laser system 401 configured to hit one or more of the fuel targets 403′ with one or more laser beams 402 for generating a plasma 407 at the plasma formation region 404. The radiation source SO can further include a radiation collector 405 (e.g., a radiation collector CO) configured to collect radiation emitted by the plasma 407.

### Example Thermally Actuated Cooling System

In some aspects, any of various components of lithographic apparatus 100 or lithographic 100 including radiation source SO, may comprise the thermally actuated cooling systems described further below.

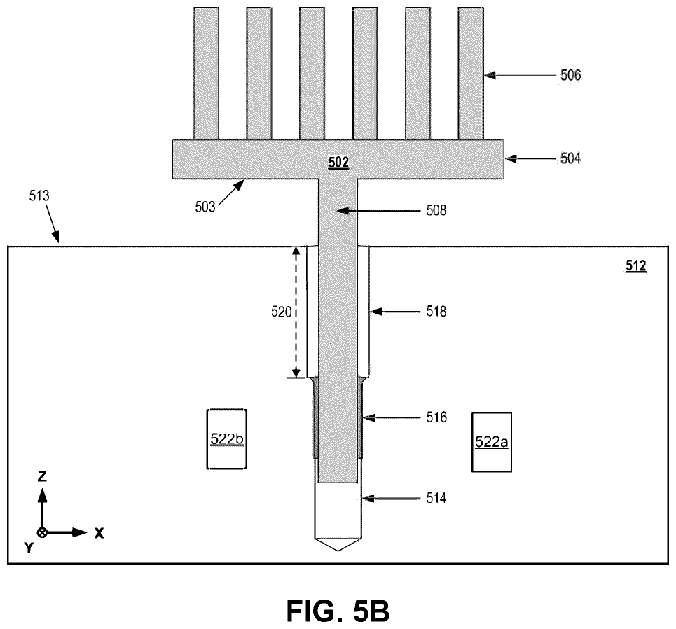

FIGS. 5A and 5B are schematic illustrations of a thermally actuated cooling system 500 according to some aspects of the present disclosure.

As shown in FIG. 5A, the thermally actuated cooling system 500 can include a cooling member 502. The cooling member 502 can include, for example, a contact plate 504, fins 506 extending from the contact plate 504 in a first direction (e.g., along the positive Z-axis), and, a protuberance 508 extending from the contact plate 504 in a second direction (e.g., substantially opposite the first direction, such as along the negative Z-axis) and configured to couple the contact plate 504 to a part 512 of an EUV radiation source (e.g., radiation source SO shown in FIG. 4). Protuberance 508 may be of various suitable shapes and dimensions in correspondence with receptacle 514. The part 512 can include, for example, the fuel target generator 403 (e.g., a DGA), any other suitable part, component, or structure, or any portion thereof.

In some aspects, the fins 506 can include rods. According to other aspects, fins 506 may take other shapes such as curved or bent, they may include various aspect ratios and sizes and may be spaced from one another at various distances. Various numbers of fins in various arrangements may extend from contact plate 504. In some aspects, the protuberance 508 can include a threaded rod or post. In some aspects, the protuberance 508 can be further configured to be partially surrounded by an annular member 516 and disposed in a receptacle 514 of the part 512. In some aspects, the receptacle 514 can include a tapped hole. In some aspects, the receptacle 514 can be threaded to mate with the protuberance 508. Receptacle 514 may be of various depths and diameters in correspondence with protuberance 508. In some aspects, the annular member 516 can include a stainless steel insert (e.g., an N60 insert). In some aspects, the part 512 can further include a counterbore 518 with a precision-controlled depth 520. The counterbore 518 may limit the contact between the cooling member 502 and the part 512 to the annular membrane 516 when the contact plate 504 is disengaged from part 512, as shown and described in FIG. 5B.

In some aspects, the contact plate 504 can have a first CTE that is greater than a second CTE of the part 512. For example, the contact plate 504 can include aluminum and have a first CTE of about 22.0 to 24.0×10⁻⁶ K⁻¹ at about 25° C., and the part 512 can include molybdenum and have a second CTE of about 4.0 to 6.0×10⁻⁶ K⁻¹ at about 25° C. As a result, the second CTE of the part 512 can be about 75 to 85 percent lower than the first CTE of the contact plate 504. According to other aspects, contact plate 504 and part 512 may be formed of various other materials and various other suitable CTE's and relative CTE's may be used.

In some aspects, the protuberance 508 can be configured to be in a physically strained relationship with the part 512.

In some aspects, the part 512 can include a heating element 522. The heating element 522 may be various cartridge heaters, ceramic heaters, and the like. In some aspects, the part 512 can include additional heating elements. In some aspects, the heating element 522 may be actuated independently of the EUV radiation source. For example, the heating element 522 may be turned on before EUV production starts and may remain on until after EUV production ends. The heating element 522 may heat the part 512 and the protuberance 508.

In some embodiments, a controller may actuate the heating element 522. In some aspects, controller 411 can be used to actuate the heating element 522. In some aspects, another controller (not shown) may be coupled to the heating element 522. The controller may control a switch configured to turn the heating element 522 on or off. The controller may be configured to control the heating element 522 based on an operation status of the radiation source SO. For example, the controller may turn on the heating element 522 when the radiation source SO is on or before the radiation source is turned on (e.g., based on a preset schedule). The controller may turn off the heating element 522 when the radiation source SO is turned off or after a preset time period after the radiation source is turned off.

In some embodiments, a thermocouple 524 (or other temperature-measurement devices) can be coupled to the heating element 522. In some aspects, the part 512 can include the thermocouple 524. In some aspects, the thermocouple 524 may also be coupled to the controller. The thermocouple 524 can be used in a control loop with the heating element 522 to maintain target temperatures. In some embodiments, the controller may compare a temperature received from the thermocouple 524 with a target temperature. The controller may turn on or off the heating element 522 based on the comparison. The position of the heating element 522 in FIG. 5A is for illustration purposes only. The heating element and the thermocouple 524 may be positioned at other locations in the part 512.

Part 512 may operate at elevated temperatures and thus may be heated due to various other means.

For example, as shown in FIG. 5B, when the part 512 is heated such as when it is exposed to heat from the heating element 522, a first surface 503 of the contact plate 504 is configured to disengage from a second surface 513 of the part 512 (e.g., to deactivate additional cooling of the part 512 by the fins 506 during the EUV radiation generation operation). In another example, as shown in FIG. 5A, when the part 512 is not exposed to heat from the heating element 522 (e.g., heating elements are turned off), the first surface 503 of the contact plate 504 is configured to contact the second surface 513 of the part 512.

In one illustrative and non-limiting example embodiment, the part 512 can be a molybdenum part that is a component of an EUV radiation source (e.g., radiation source SO shown in FIG. 4) and operates at elevated temperatures. In some aspects, the cooling member 502 can be an aluminum member having a protuberance 508 (e.g., an aluminum threaded post) and can be joined to the part 512 using torque, where the torque applied determines the strain in the protuberance 508. The cooling member 502 and the part 512 can be assembled at room temperature. As the assembly heats up, the molybdenum of the part 512 and the aluminum of the cooling member 502 can expand at different rates (e.g., molybdenum CTE is about 5.2 ppm/K; aluminum CTE is about 23.1 ppm/K). The aluminum protuberance 508 expands faster than the molybdenum part 512 and the strain in the protuberance 508 can relax at a rate of about 17.9 ppm/K. Once the strain is substantially fully relaxed, the contact plate 504 can lift off of the part 512, and the conductive heat transfer to the fins 506 can now be limited by the annular member 516 (e.g., an N60 stainless steel insert). Upon cooling, the protuberance 508 can shrink faster than the part 512, eventually bringing the contact plate 504 back into contact with the part 512 thus cooling part 512. The temperature that the contact plate 504 makes contact with the part 512 can be tuned by varying the thread diameter used, the precision-controlled depth 520 of the counterbore 518, the torque applied during assembly, and the materials used.

In some aspects, without the thermally actuated cooling system 500 (and without permanent fins), the heat transferred from the part 512 may be determined according to Equation 1:

$$q = \overline{h} A ( {T}_{S} - {T}_{∞} ) \qquad ( 1 )$$

where q represents the heat transfer rate, h̅ represents the convective heat transfer coefficient, A represents the area of the cooled surface, Tₛ represents the temperature of the part 512, and T_{∞} represents the temperature of the surrounding environment.

In some aspects, with the addition of the thermally actuated cooling system 500 (e.g., thermally actuated fins), the heat transferred may rather be determined according to Equation 2:

$${q}^{′} = q + N {η}_{f} \overline{h} A ( {T}_{S} - {T}_{∞} ) \qquad ( 2 )$$

where q′ represents the modified heat transfer rate (e.g., with the addition of the thermally actuated cooling system 500), q represents the heat transfer rate given by Equation 1 (e.g., without the addition of the thermally actuated cooling system 500), N represents the number of fins (e.g., included in fins 506) and n_{f} represents the efficiency of each fin.

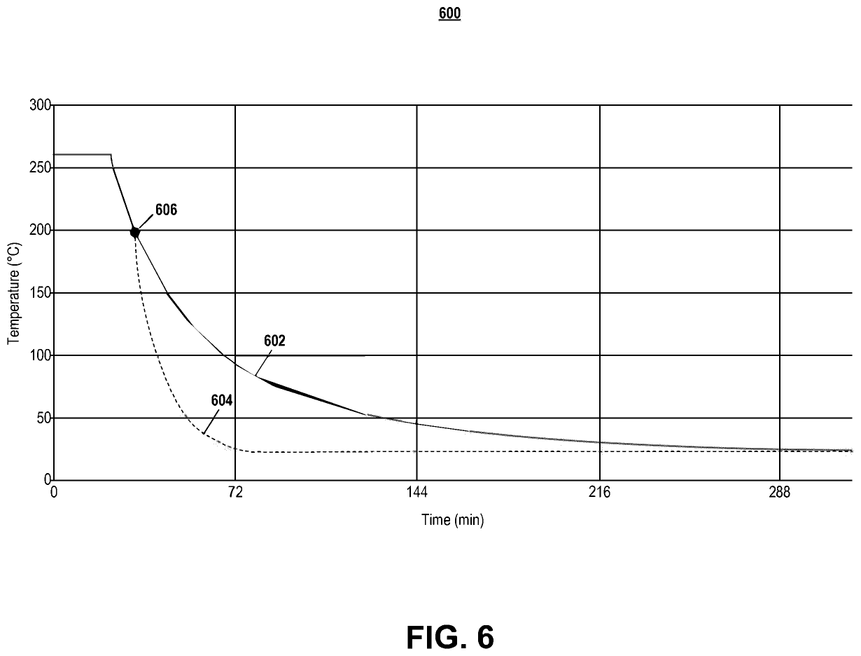

FIG. 6 is a graphical representation of a notional cooling profile resulting from an addition of the thermally actuated cooling system 500 shown in FIG. 5 to a part of a lithographic apparatus, such as a DGA, according to some aspects of the present disclosure. As shown in FIG. 6, experimental temperature measurement signal 602 represents the experimental cooling profile of a DGA, which took about two hours to cool from operational temperatures (e.g., greater than about 250° C.) to touch-safe temperatures (e.g., less than about 50° C.). As further shown in FIG. 6, notional temperature measurement signal 604 represents the notional cooling profile of the DGA with the addition of the thermally actuated cooling system 500 shown in FIG. 5, which only takes about one hour to cool from operational temperatures to touch-safe temperatures. As further shown in FIG. 6, the rate of cooling of the experimental temperature measurement signal 602 and the rate of cooling of the notional temperature measurement signal 604 are about the same until point 606 (e.g., about 250° C.), when the contact plate 504 (e.g., aluminum) makes contact with the part 512 (e.g., molybdenum). At point 606, the rate of cooling of the notional temperature measurement signal 604 sharply increases, improving the cooling time of the DGA substantially.

### Example Processes for Manufacturing an Apparatus

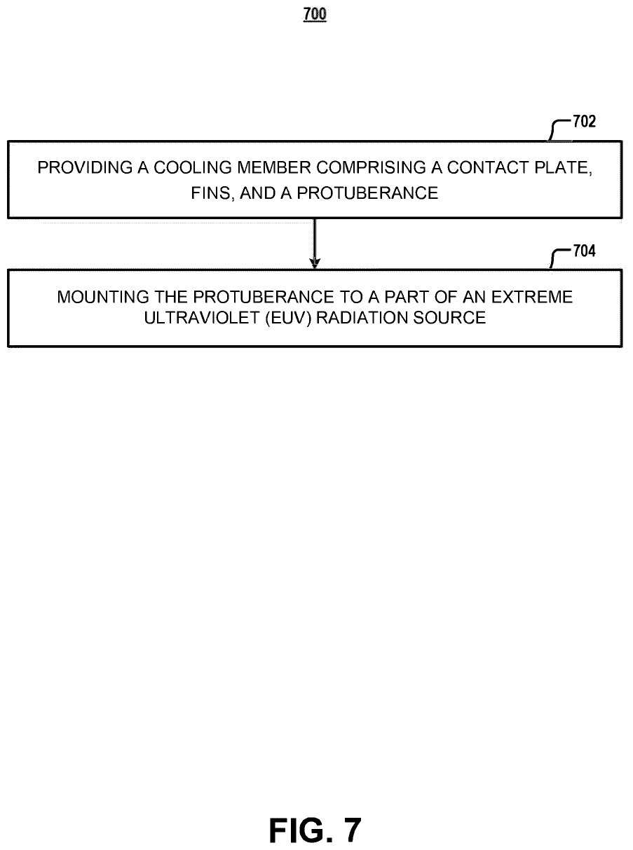

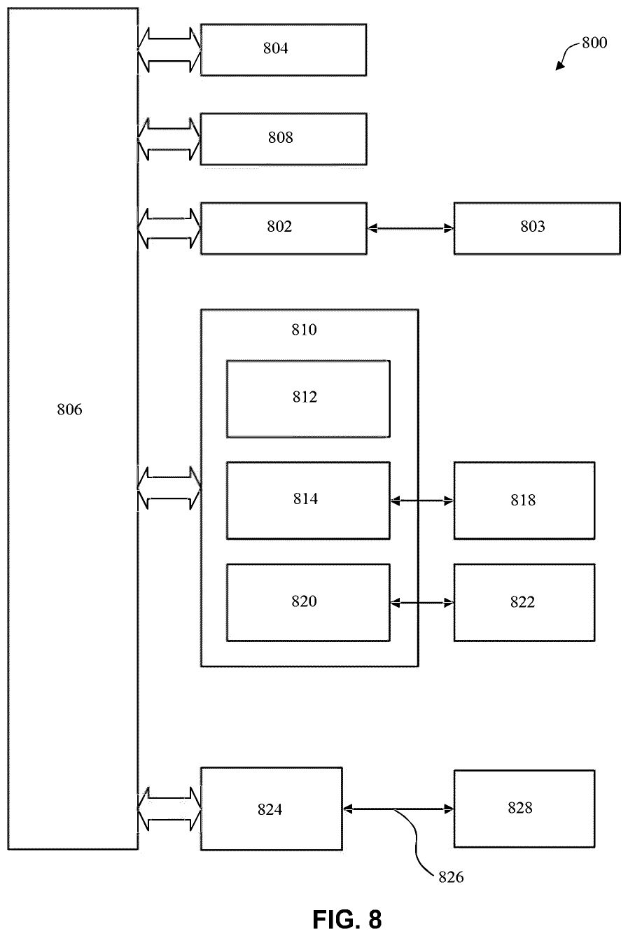

FIG. 7 is a method 700 for manufacturing an apparatus according to some aspects of the present disclosure or portion(s) thereof. The operations described with reference to method 700 can be performed by, or according to, any of the systems, apparatuses, components, techniques, or combinations thereof described herein, such as those described with reference to FIGS. 1-6 above and FIG. 8 below.

At operation 702, the method can include providing a cooling member (e.g., cooling member 502). In some aspects, the cooling member can include a contact plate (e.g., contact plate 504), fins (e.g., fins 506) extending from the contact plate in a first direction, and a protuberance (e.g., protuberance 508) extending from the contact plate in a second direction (e.g., substantially opposite the first direction). In some aspects, the cooling member can be provided using suitable optical, electrical, mechanical, or other methods and include providing the cooling member in accordance with any aspect or combination of aspects described with reference to FIGS. 1-6 above and FIG. 8 below.

At operation 704, the method can include mounting the protuberance to a part (e.g., part 512) of an EUV radiation source (e.g., radiation source SO). The contact plate can include a first CTE that is greater than a second CTE of the part. For example, the contact plate can include aluminum, the part can include molybdenum, and a first CTE of the aluminum can be greater than a second CTE of the molybdenum. In some aspects, the mounting the protuberance to the part can include: mounting an annular member (e.g., annular member 516) to the protuberance, where the annular member partially surrounds the protuberance; and disposing the protuberance and the annular member in a receptacle (e.g., receptacle 514) of the part. In some aspects, when the protuberance is mounted to the part, the protuberance can be in a physically strained relationship with the part such that: (i) when the part is exposed to heat (e.g., when the heating element 522 of part 512 are turned on or when operating at an elevated temperature), a first surface (e.g., first surface 503) of the contact plate is configured to disengage (e.g., as shown in FIG. 5B) from a second surface of the part (e.g., second surface 513); and (ii) when the part is not exposed to heat, the first surface of the contact plate is configured to contact (e.g., as shown in FIG. 5A) the second surface of the part. In some aspects, the mounting of the protuberance to the part can be accomplished using suitable optical, electrical, mechanical, or other methods and include mounting the protuberance to the part in accordance with any aspect or combination of aspects described with reference to FIGS. 1-6 above and FIG. 8 below.

### Example Computing System

Aspects of the disclosure can be implemented in hardware, firmware, software, or any combination thereof. For example, the design of one or more of the materials of the contact plate 504 and part 512, CTE's, relative CTE's, dimensions of the receptacle 514, the precision-controlled depth 512 may be implemented using hardware, firmware, software, or any combination thereof. Aspects of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions, and combinations thereof can be described herein as performing certain actions. However, it should be appreciated that such descriptions are merely for convenience and that such actions in fact result from computing devices, processors, controllers, or other devices executing the firmware, software, routines, instructions, or combinations thereof and, in doing so, causing actuators or other devices (e.g., servo motors, robotic devices) to interact with the physical world.

Various aspects can be implemented, for example, using one or more computing systems, such as computing system 800 shown in FIG. 8. Computing system 800 can be a specialized computer capable of performing the functions described herein such as: the laser system 401 described with reference to FIG. 4; the thermally actuated cooling system 500 described with reference to FIG. 5; any other suitable system, sub-system, or component; or any combination thereof. Computing system 800 can include one or more processors (also called central processing units, or CPUs), such as a processor 804. Processor 804 is connected to a communication infrastructure 806 (e.g., a bus). Computing system 800 can also include user input/output device(s) 803, such as monitors, keyboards, pointing devices, etc., that communicate with communication infrastructure 806 through user input/output interface(s) 802. Computing system 800 can also include a main memory 808 (e.g., one or more primary storage devices), such as random access memory (RAM). Main memory 808 can include one or more levels of cache. Main memory 808 has stored therein control logic (e.g., computer software) and/or data.

Computing system 800 can also include a secondary memory 810 (e.g., one or more secondary storage devices). Secondary memory 810 can include, for example, a hard disk drive 812 and/or a removable storage drive 814. Removable storage drive 814 can be a floppy disk drive, a magnetic tape drive, a compact disk drive, an optical storage device, tape backup device, and/or any other storage device/drive.

Removable storage drive 814 can interact with a removable storage unit 818. Removable storage unit 818 includes a computer usable or readable storage device having stored thereon computer software (control logic) and/or data. Removable storage unit 818 can be a floppy disk, magnetic tape, compact disk, DVD, optical storage disk, and/or any other computer data storage device. Removable storage drive 814 reads from and/or writes to removable storage unit 818.

According to some aspects, secondary memory 810 can include other means, instrumentalities or other approaches for allowing computer programs and/or other instructions and/or data to be accessed by computing system 800. Such means, instrumentalities or other approaches can include, for example, a removable storage unit 822 and an interface 820. Examples of the removable storage unit 822 and the interface 820 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computing system 800 can further include a communications interface 824 (e.g., one or more network interfaces). Communications interface 824 enables computing system 800 to communicate and interact with any combination of remote devices, remote networks, remote entities, etc. (individually and collectively referred to as remote devices 828). For example, communications interface 824 can allow computing system 800 to communicate with remote devices 828 over communications path 826, which can be wired and/or wireless, and which can include any combination of LANs, WANs, the Internet, etc. Control logic, data, or both can be transmitted to and from computing system 800 via communications path 826.

The operations in the preceding aspects of the present disclosure can be implemented in a wide variety of configurations and architectures. Therefore, some or all of the operations in the preceding aspects can be performed in hardware, in software or both. In some aspects, a tangible, non-transitory apparatus or article of manufacture includes a tangible, non-transitory computer useable or readable medium having control logic (software) stored thereon is also referred to herein as a computer program product or program storage device. This includes, but is not limited to, computing system 800, main memory 808, secondary memory 810 and removable storage units 818 and 822, as well as tangible articles of manufacture embodying any combination of the foregoing. Such control logic, when executed by one or more data processing devices (such as computing system 800), causes such data processing devices to operate as described herein.

Based on the teachings contained in this disclosure, it will be apparent to persons skilled in the relevant art(s) how to make and use aspects of the disclosure using data processing devices, computer systems and/or computer architectures other than that shown in FIG. 8. In particular, aspects of the disclosure can operate with software, hardware, and/or operating system implementations other than those described herein.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

Other aspects of the invention are set out in the following numbered clauses:
1. A system comprising:
a cooling member comprising:
a contact plate;
fins extending from the contact plate in a first direction; and
a protuberance extending from the contact plate in a second direction and configured to couple the contact plate to a part of an extreme ultraviolet (EUV) radiation source,
wherein the contact plate comprises a first coefficient of thermal expansion (CTE) that is greater than a second CTE of the part.
2. The system of clause 1, wherein the part of the EUV radiation source includes a heating element and wherein the protuberance is configured to be in a physically strained relationship with the part such that:
when the part is heated by the heating element, a first surface of the contact plate is configured to disengage from a second surface of the part; and
when the part is not exposed to heat, the first surface of the contact plate is configured to contact the second surface of the part.
3. The system of clause 1, wherein the fins comprise rods.
4. The system of clause 1, wherein the protuberance comprises a threaded rod.
5. The system of clause 1, wherein:
the contact plate comprises aluminum; and
the part comprises molybdenum.
6. The system of clause 1, wherein the protuberance is further configured to be partially surrounded by an annular member and disposed in a receptacle of the part.
7. The system of clause 6, wherein the receptacle comprises a tapped hole and the protuberance comprises a threaded rod.
8. The system of clause 6, wherein the annular member comprises a stainless steel insert, the contact plate comprises aluminum and the part comprises molybdenum.
9. An apparatus, comprising:
a contact plate; and
a protuberance extending from the contact plate and configured to couple the contact plate to a part of an extreme ultraviolet (EUV) radiation source, wherein the protuberance is configured to be in a physically strained relationship with the part such that:
when the part is heated, a first surface of the contact plate is configured to disengage from a second surface of the part; and
when the part is not exposed to heat, the first surface of the contact plate is configured to contact the second surface of the part.
10. The apparatus of clause 9, further comprising fins extending from the contact plate in a first direction, and wherein the protuberance extends in a second opposed direction.
11. The apparatus of clause 10, wherein the fins comprise rods and the part includes a heating element.
12. The apparatus of clause 9, wherein the protuberance comprises a threaded rod and is configured to be received in a receptacle of the part.
13. The apparatus of clause 9, wherein:
the contact plate comprises aluminum; and
the part comprises molybdenum.
14. The apparatus of clause 9, wherein the protuberance is further configured to be partially surrounded by an annular member and disposed in a receptacle of the part.
15. The apparatus of clause 14, wherein the contact plate comprises aluminum, the part comprises molybdenum and the annular member comprises a stainless steel.
16. The apparatus of clause 12, wherein the receptacle comprises a tapped hole.
17. A method comprising:
providing a cooling member comprising:
a contact plate,
fins extending from the contact plate in a first direction, and
a protuberance extending from the contact plate in a second direction; and
mounting the protuberance to a part of an extreme ultraviolet (EUV) radiation source,
wherein the contact plate comprises a first coefficient of thermal expansion (CTE) that is greater than a second CTE of the part.
18. The method of clause 17, wherein, when the protuberance is mounted to the part, the protuberance is in a physically strained relationship with the part such that:
when the part is heated, a first surface of the contact plate is configured to disengage from a second surface of the part; and
when the part is not exposed to the heat, the first surface of the contact plate is configured to contact the second surface of the part.
19. The method of clause 18, wherein the protuberance is threaded, and the method further comprising:
mounting the protuberance by engaging the protuberance with corresponding threads of a threaded receptacle of the part, and wherein the strain in the protuberance is relaxed when the part is heated.
20. The method of clause 17, wherein:
the contact plate comprises aluminum; and
the part comprises molybdenum.
21. The method of clause 17, wherein the mounting the protuberance to the part comprises:
mounting an annular member to the protuberance, wherein the annular member partially surrounds the protuberance; and
disposing the protuberance and the annular member in a receptacle of the part.

The breadth and scope of the present disclosure should not be limited by any of the above-described example aspects or embodiments, but should be defined only in accordance with the following claims and their equivalents.

1. A system comprising:
a cooling member comprising:
a contact plate;
fins extending from the contact plate in a first direction; and
a protuberance extending from the contact plate in a second direction and configured to couple the contact plate to a part of an extreme ultraviolet (EUV) radiation source,
wherein the contact plate comprises a first coefficient of thermal expansion (CTE) that is greater than a second CTE of the part.

2. The system of claim 1, wherein the part of the EUV radiation source includes a heating element and wherein the protuberance is configured to be in a physically strained relationship with the part such that:
when the part is heated by the heating element, a first surface of the contact plate is configured to disengage from a second surface of the part; and
when the part is not exposed to heat, the first surface of the contact plate is configured to contact the second surface of the part.

3. The system of claim 1, wherein the fins comprise rods.

4. The system of claim 1, wherein the protuberance comprises a threaded rod.

5. The system of claim 1, wherein:
the contact plate comprises aluminum; and
the part comprises molybdenum.

6. The system of claim 1, wherein the protuberance is further configured to be partially surrounded by an annular member and disposed in a receptacle of the part.

7. The system of claim 6, wherein the receptacle comprises a tapped hole and the protuberance comprises a threaded rod.

8. The system of claim 6, wherein the annular member comprises a stainless steel insert, the contact plate comprises aluminum and the part comprises molybdenum.

9. An apparatus, comprising:
a contact plate; and
a protuberance extending from the contact plate and configured to couple the contact plate to a part of an extreme ultraviolet (EUV) radiation source, wherein the protuberance is configured to be in a physically strained relationship with the part such that:
when the part is heated, a first surface of the contact plate is configured to disengage from a second surface of the part; and
when the part is not exposed to heat, the first surface of the contact plate is configured to contact the second surface of the part.

10. The apparatus of claim 9, further comprising fins extending from the contact plate in a first direction, and wherein the protuberance extends in a second opposed direction.

11. The apparatus of claim 10, wherein the fins comprise rods and the part includes a heating element.

12. The apparatus of claim 9, wherein the protuberance comprises a threaded rod and is configured to be received in a receptacle of the part.

13. The apparatus of claim 9, wherein:
the contact plate comprises aluminum; and
the part comprises molybdenum.

14. The apparatus of claim 9, wherein the protuberance is further configured to be partially surrounded by an annular member and disposed in a receptacle of the part.

15. The apparatus of claim 14, wherein the contact plate comprises aluminum, the part comprises molybdenum and the annular member comprises a stainless steel.

16. The apparatus of claim 12, wherein the receptacle comprises a tapped hole.

17. A method comprising:
providing a cooling member comprising:
a contact plate,
fins extending from the contact plate in a first direction, and
a protuberance extending from the contact plate in a second direction; and
mounting the protuberance to a part of an extreme ultraviolet (EUV) radiation source,
wherein the contact plate comprises a first coefficient of thermal expansion (CTE) that is greater than a second CTE of the part.

18. The method of claim 17, wherein, when the protuberance is mounted to the part, the protuberance is in a physically strained relationship with the part such that:
when the part is heated, a first surface of the contact plate is configured to disengage from a second surface of the part; and
when the part is not exposed to the heat, the first surface of the contact plate is configured to contact the second surface of the part.

19. The method of claim 18, wherein the protuberance is threaded, and the method further comprising:
mounting the protuberance by engaging the protuberance with corresponding threads of a threaded receptacle of the part, and wherein the strain in the protuberance is relaxed when the part is heated.

20. The method of claim 17, wherein:
the contact plate comprises aluminum; and
the part comprises molybdenum.

21. The method of claim 17, wherein the mounting the protuberance to the part comprises:
mounting an annular member to the protuberance, wherein the annular member partially surrounds the protuberance; and
disposing the protuberance and the annular member in a receptacle of the part.
